(19) United States
(12) Patent Application Publication
(10) Pub. No.: US 2014/0076525 A1
(43) Pub. Date: Mar. 20, 2014

(54) TEMPERATURE-CONTROL ELEMENT AND METHOD FOR ATTACHING AN ELECTRONIC COMPONENT TO THE TEMPERATURE-CONTROL ELEMENT

(71) Applicants: Andy Mantey, Gifting (DE); Johannes Dippold, Bamberg (DE)

(72) Inventors: Andy Mantey, Gifting (DE); Johannes Dippold, Bamberg (DE)

(21) Appl. No.: 13/985,710

(22) PCT Filed: Feb. 15, 2012
(86) PCT No.: PCT/EP2012/052576

§ 371 Date: Nov. 26, 2013

(30) Foreign Application Priority Data
Feb. 15, 2011 (DE) 10 2011 004 171.0

(51) Int. Cl. F28F 13/18; H05K 7/20; B21D 53/02; F28F 21/08

(52) U.S. Cl. CPC F28F 13/185; F28F 21/089; H05K 7/20509; B21D 53/02
USPC 165/133; 165/185; 29/890.03

(57) ABSTRACT

The present invention relates to a temperature-control element. The present invention relates to a temperature-control element, having at least one surface region with an electrically insulating and thermally conductive coating, in particular a ceramic coating provided on said surface region, and attached to the coating is at least one electronic component which is thermally connected to the temperature-control element and is configured to be electrically insulating with respect to the temperature-control element. The present invention also relates to a method for attaching an electronic component to the temperature-control element.

This application is based on and claims the benefit of priority from German Patent Application DE 10 2011 004 171.0, filed on Feb. 15, 2011, the contents of which are incorporated by reference.

### FIELD OF THE INVENTION

The present invention relates to a temperature-control element. It also relates to a method for attaching an electronic component to the temperature-control element.

### TECHNICAL BACKGROUND

Injection-moulded parts, inter alia, having a specific surface finish and surface cleanness are used in electronic engineering. Electrical components are attached to these injection-moulded parts, for example to a housing of a radiator fan motor of a vehicle. In this respect, the electrical components can be cooled by a cooling element. However, various problems can arise here. For example, a short circuit can result between the electrical component and the injection-moulded housing if the electrical component is attached to the injection-moulded housing in an inappropriately electrically insulated manner. Furthermore, the electrical component can be cooled insufficiently and damaged thereby if it is thermally insulated from the injection-moulded housing of the radiator fan motor, because the spacing between the electrical component and the injection-moulded housing of the radiator fan motor is too great due, for example, to unevennesses of the housing. As a result, there is poor thermal conductivity between the electrical component and the injection-moulded housing.

The objective is to improve this situation.

### SUMMARY OF THE INVENTION

Against this background, the object of the present invention is to provide an improved attachment of an electronic component to a cooling element.

This object is achieved according to the invention by a temperature-control element having the features of claim 1 and/or by a method having the features of claim 13.

Accordingly, there is provided:
a temperature-control element, having at least one surface region with an electrically insulating and thermally conductive coating, in particular a ceramic coating, for example an electro-ceramic coating provided thereon, and attached to the coating is at least one electronic component which is thermally connected to the temperature-control element and is configured to be electrically insulating with respect to the temperature-control element.
A method for attaching at least one electronic component to a temperature-control element, comprising the following steps: providing a temperature-control element; applying an electrically insulating and thermally conductive coating, in particular a ceramic coating, for example an electro-ceramic coating, to at least one surface region of the temperature-control element; attaching at least one electronic component to the coating of the temperature-control element, the electronic component being thermally connected to the temperature-control element and being electrically insulated from the temperature-control element.

The fundamental recognition/idea of the present invention is to provide a temperature-control element with an electrically insulating and thermally conductive coating, in particular a ceramic coating, in order to attach an electronic component thereto so that on the one hand, the electronic component can be connected thermally to the temperature-control element while on the other hand, it is also electrically insulated from the temperature-control element.

Advantageous configurations and developments are provided in the further dependent claims and in the description with reference to the figures of the drawings.

In an embodiment according to the invention, the at least one surface region is treated by a blasting method, in particular by sandblasting, blasting with corundum, by shot peening, metal blasting and/or glass blasting. This affords the advantage that, for example, unevennesses such as burrs can be removed from the surface region and the surface region can be provided with, for example, a predetermined or defined surface roughness. This additionally improves the adhesion of the coating or of an additional intermediate layer.

In a further embodiment according to the invention, as a result of the treatment by the blasting method, the at least one surface region has a defined surface roughness, preferably a surface roughness within a range of R_{z}=20 μm to R_{z}=60 μm. In this manner, the adhesion of the subsequently applied coating or additional intermediate layer can be further improved.

According to an embodiment of the invention, the at least one surface region is provided with at least one intermediate layer, said intermediate layer being configured in particular as an adhesive base for the coating. The intermediate layer also improves the adhesion of the coating.

In an embodiment of the invention, the intermediate layer is a metal alloy and in particular, for example, a nickel, chromium, copper and/or aluminium alloy.

According to a further embodiment of the invention, the intermediate layer is applied to the at least one surface region by thermal spraying. The advantage of thermal spraying is that the surface region is subjected to hardly any thermal stress.

In one embodiment of the invention, the electrically insulating and thermally conductive coating, in particular a ceramic coating, for example an electro-ceramic coating is applied to the surface region in order to even out unevennesses and/or impurities of the surface region. In this manner, unevennesses in the surface which would otherwise result in an impaired thermal connection of the electronic component, can be at least partly or completely evened out and levelled. Furthermore, it is possible to correct impurities of the surface which could otherwise, in certain circumstances, lead to short circuits with the electronic component.

In a further embodiment according to the invention, the electronic component is connected to the electrically insulating and thermally conductive coating on the surface region by means of a thermal interface material or thermal connecting material, such as a thermally conductive paste, in particular a glass bead adhesive or another thermally conductive paste. The advantage of the thermal interface material or of the thermal connecting material, such as the thermally conductive paste is that the electronic component can be joined to the temperature-control element in a very simple thermal manner. The electrically insulating and thermally conductive coating, in particular a ceramic coating, such as an electro-ceramic coating also has a very good thermal conductivity and, at the same time, electrically insulates the electronic component from the temperature-control element.

In a further embodiment according to the invention, the coating is for example a ceramic coating such as an electro-ceramic, of aluminium oxide, Al₂O₃, a mixture of 97% Al₂O₃, and 3% TiO₂, MgAl₂O₄ and/or magnesium oxide. Aluminium oxide is characterised by outstanding material characteristics, such as dielectric strength at elevated temperatures. Furthermore, magnesium oxide is characterised by a good electrical insulating power at elevated temperatures, at the same time with a very good thermal conductivity.

In another embodiment according to the invention, the electrically insulating and thermally conductive coating, for example a ceramic coating, such as an electro-ceramic coating, etc. is applied to the surface region of the temperature-control element as granules (for example as ceramic granules) by means of a plasma jet in order to coat the surface region. In this respect, the coating is simultaneously applied in the surface by the plasma jet and a very stable coating of the surface is obtained. Apart from the plasma spraying process, other thermal spraying processes can also be used to apply the coating, for example flame spraying, in particular high-velocity flame spraying, etc.

According to another embodiment of the invention, the temperature-control element is a cooling element, in particular a housing of a radiator fan motor of a vehicle. The radiator fan motor can be used to take up and remove the heat generated by the electronic component attached thereto.

The above configurations and developments can be combined with one another in any desired, appropriate manner. Further possible configurations, developments and implementations of the invention also include combinations, not mentioned explicitly, of features of the invention which have been described previously or which will be described in the following with respect to the embodiments. In particular, a person skilled in the art will also add individual aspects as improvements or supplements to the respective basic form of the present invention.

### SUMMARY OF THE DRAWINGS

In the following, the present invention will be described in more detail with reference to the embodiments provided in the schematic figures of the drawings.

FIG. 1 is a sectional view of a detail of a connection of a cooling element to electrical components, according to a first embodiment of the invention;

FIG. 2 is a sectional view of a detail of a connection of a cooling element to electrical components, according to a second embodiment of the invention;

FIG. 3 is a plan view of a housing of a radiator fan motor of a vehicle, having a full-surface ceramic coating;

FIG. 4 is a plan view of a housing of a radiator fan motor of a vehicle, having a ceramic coating of functional surfaces;

FIG. 5 is a flow chart for connecting or attaching an electronic component to a cooling element according to the first embodiment of the invention; and

FIG. 6 is a flow chart for connecting or attaching an electronic component to a cooling element according to the second embodiment of the invention.

The accompanying drawings are to provide a further understanding of the embodiments of the invention. They illustrate embodiments and, together with the description, are used to explain principles and concepts of the invention. Other embodiments and many of the mentioned advantages are revealed from the drawings. The elements of the drawings have not necessarily been shown true-to-scale relative to one another.

In the figures of the drawings, identical, functionally identical and identically operating elements, features and components have been provided with the same reference numerals in each case, unless indicated otherwise.

### DETAILED DESCRIPTION

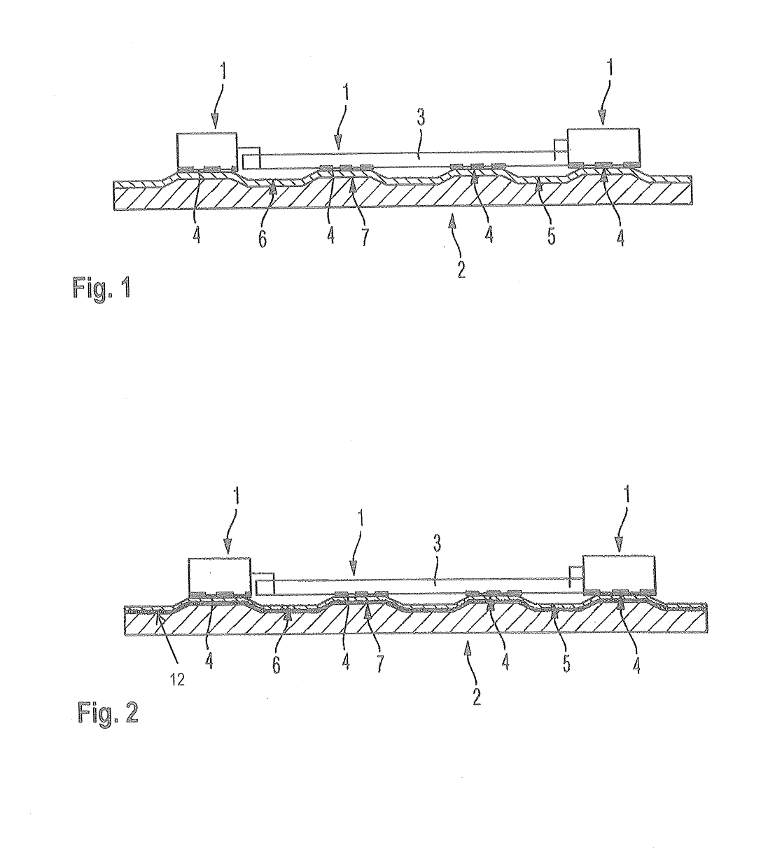

FIG. 1 is a sectional view, according to a first embodiment of the invention, of the attachment of a plurality of electronic components 1 to a temperature-control element 2, in this case, for example, a cooling element.

FIG. 2 is a sectional view, according to a second embodiment of the invention, also of the attachment of a plurality of electronic components 1 to a temperature-control element 2.

The first and second embodiments of the invention differ from one another in that in the second embodiment, an additional intermediate layer 12 is applied as an adhesive base to the temperature-control element 2, in this case, for example, to the cooling element.

The two sectional views of the electronic components 1 and of the cooling element 2 are shown in a purely schematic, greatly simplified manner and are not true to scale.

Electronic components 1 or power components which transmit heat, for example transistors, FETs, voltage regulators, circuit boards 3 with circuits and components etc. can be thermally connected to a cooling element 2 in order to be cooled. For this purpose, the electronic components 1 are connected to the cooling element 2 by a thermal interface material or thermal connecting material, such as a thermally conductive paste 4 (indicated in FIG. 1 by a dashed line). In FIG. 1, a thermally conductive paste 4 is used. However, the invention is not restricted to a thermally conductive paste. It is possible for any other thermal interface material or thermal connecting or joining material to be used.

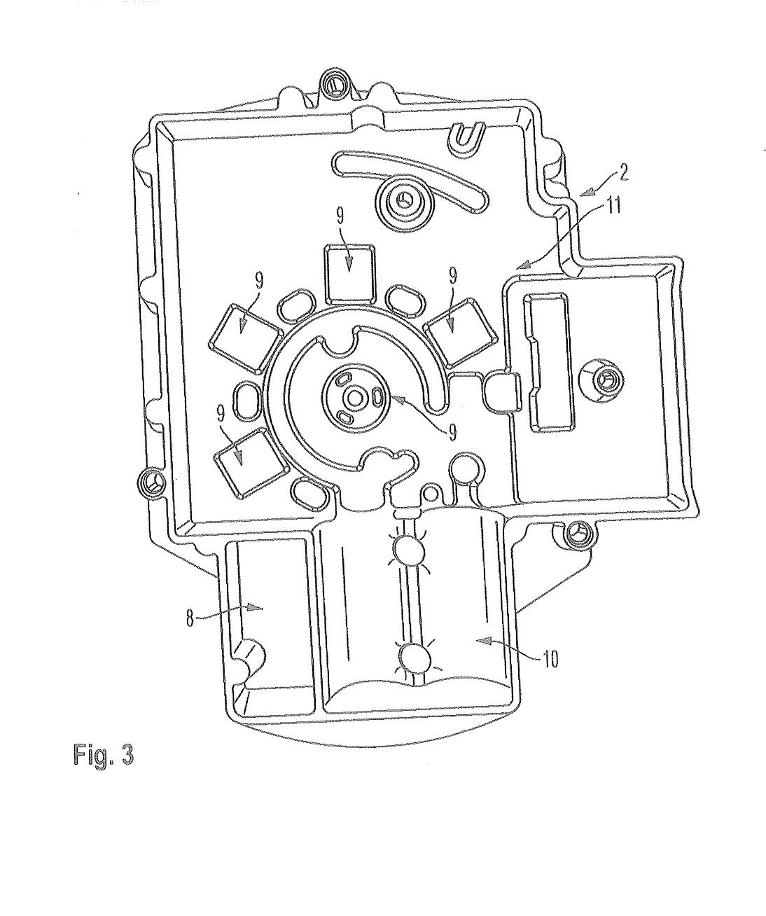

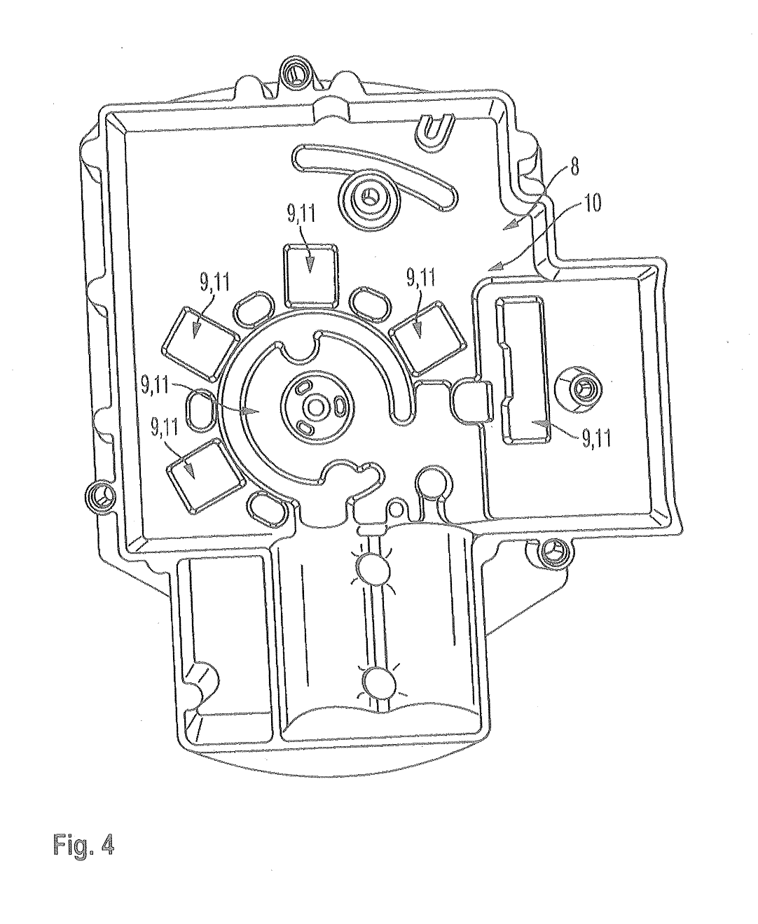

The cooling element 2 is, for example, a housing, in particular a housing of a radiator fan motor, such as an injection moulded housing of a radiator fan motor of a vehicle, as shown in the following FIGS. 3 and 4. However, the invention is not restricted to a housing of a radiator fan motor or to an injection moulded housing.

A glass bead adhesive or another thermally conductive paste or combination of thermally conductive pastes is used, for example, as the thermally conductive paste 4 for connecting the respective electronic component 1. As already stated, apart from a thermally conductive paste, it is also possible to use any other thermal interface material or thermal connecting or joining material.

As shown in FIGS. 1 and 2, the surface of the cooling element 1, for example an injection moulded housing of a radiator fan motor of a vehicle, can exhibit unevennesses 5 and/or impurities. The result of unevennesses 5 and impurities of this type can be that during the attachment of an electronic component 1, a short circuit may occur or the thermal connection of the electronic component 1 to the cooling element 2 may be inadequate, and thus the electronic component 1 cannot be cooled adequately.

For this reason, according to the invention, the cooling element 2 is provided with a coating in at least one surface region or the entire surface or substantially the entire surface is provided with a coating, said coating being selected to be on the one hand electrically insulating and on the other, thermally conductive. Thereafter, the respective electronic component 1 is connected to the cooling element 2 covered with the coating 6 by a thermal interface material or thermal connecting material, such as the thermally conductive paste 4, as shown in FIGS. 1 and 2. In this respect, a glass bead adhesive can be used as the thermally conductive paste 4, as stated above. However, instead of the glass bead adhesive, it is also possible to use any other thermally conductive paste and any other thermal interface material or thermal connecting or joining material. In particular, thermally conductive pastes which are cheaper than glass bead adhesives can also be used.

In the first embodiment of the invention, as shown in FIG. 1, a ceramic coating, such as an electro-ceramic coating 6 as an example of an electrically insulating and thermally conductive coating is applied directly to the surface of the cooling element 2.

However, in the second embodiment of the invention, as shown in FIG. 2, at least one intermediate layer is firstly applied to the surface of the cooling element 2, which intermediate layer serves as an adhesive base for the electrically insulating and thermally conductive coating, here for example the electro-ceramic coating 6. The electro-ceramic coating 6 is then applied to the intermediate layer. At least one electronic component 1 is then joined to the electro-ceramic coating 6 by means of a thermally conductive paste 4.

In the case of a ceramic coating, for example an electro-ceramic coating, the ceramic material is sprayed, for example as ceramic granules, under high pressure in a plasma jet for coating, and consequently, the ceramic granules become liquefied and are deposited or applied onto the surface of the component, in this case to the surface of the cooling element 2 or, in the case of an intermediate layer, are deposited or applied onto the intermediate layer of the cooling element 2.

The method used for applying the coating, such as the ceramic coating 6 to the component 2 can be the thermal spraying process as a surface coating method. According to the invention, it is possible to use as the thermal spraying process in particular high-velocity flame spraying with a gaseous or liquid fuel and plasma spraying, for example atmospheric plasma spraying or plasma spraying using an atmospheric plasma jet, plasma spraying under inert gas or plasma spraying under low pressure (vacuum).

Thermal spraying is generally defined according to DIN EN 657. In thermal spraying, additional materials (spray additives or coating materials) are melted on or down inside or outside a spray device or spray burner, are accelerated in a gas flow as spray particles and sprayed with high velocity onto the surface of the component to be coated.

During this procedure, the surface of the component is not melted.

As stated previously, in the case of plasma spraying, a plasma jet is used as the energy carrier for the melting on or down of the spray additive (coating material). In addition, it is also possible to use as the energy carrier for the melting on or down of the spray additive (coating material) an electric arc in the case of arc spraying, an oxygen-fuel flame or high velocity oxygen-fuel flame in the case of conventional and high velocity flame spraying, a laser beam in the case of laser beam spraying and fast, preheated gases in the case of cold gas spraying. It is possible to coat metallic and non-metallic materials with, for example, oxide-ceramic materials, metals, carbide materials or composite materials etc. by means of these thermal spraying processes.

As an example of an electrically insulating and thermally conductive coating, for example a ceramic coating, such as an electro-ceramic coating 6, it is possible to use aluminium oxide, for example, such as Rapox® manufactured by Rauschert, corundum or Al₂O₃, a mixture of, for example, 97% Al₂O₃ or corundum and 3% TiO₂ or titanium dioxide, MgAl₂O₄ or spinel, or magnesium oxide etc. or another suitable ceramic material or ceramic material combination. Rapox® manufactured by Rauschert is an aluminium oxide ceramic which is characterised by outstanding material properties, such as dielectric strength at elevated temperatures. Magnesium oxide, for example, can likewise be used as the ceramic coating 6. Magnesium oxide belongs to the group of high temperature ceramic materials. It is characterised by a good electrical insulating power at elevated temperatures, at the same time with a very good thermal conductivity.

The coating of in particular at least one or all functional regions of the surface of the cooling element 2, for example of the surface of the injection moulded housing, with an electrically insulating and thermally conductive coating, such as with an electro-ceramic coating 6, affords the advantage that it is possible to achieve an improved heat dissipation from the electronic component 1 and an improved electrical insulation of the electronic component 1 from the cooling element 2. As shown in the embodiments in FIGS. 1 and 2, for example the coating 6 makes it possible for unevennesses 5 to be at least partly or completely evened out, for residual unevennesses 7 to be coated and insulated from the electronics. The cooling element 2 with its surface can thereby be insulated from the electronics or from the electronic components 1 and adequate thermal connection of the electronic component 1 to the cooling element 2 can also be achieved.

As shown in the embodiments in FIGS. 1 and 2, an extensive coating with the electrically insulating and thermally conductive coating, for example, with the electro-ceramic coating 6, of the entire or substantially the entire cooling element 2, for example of the injection moulded housing of a radiator fan motor, or of at least one surface region of the cooling element 2 can be carried out. In this respect, in the embodiment in FIG. 2, the entire or substantially the entire surface or at least one surface region can be provided with the additional intermediate layer and with the electrically insulating and thermally conductive coating, for example, with the electro-ceramic coating 6.

Thereafter, in the embodiments illustrated in FIGS. 1 and 2, at least one circuit board 3, as the electronic component 1, with one or more components and/or circuits, for example a hybrid circuit etc. thereon, can be joined by means of a thermal interface material or thermal connecting or joining material, such as a thermally conductive paste 4 to the coated surface of the cooling element 2. The thermally conductive paste 4, for example, a glass bead adhesive is just one example of a thermal interface material or thermal connecting or joining material. The invention is not restricted to a thermally conductive paste and in particular is not restricted to a glass bead adhesive.

Apart from a circuit board 3 as the electronic component 1, as shown in the embodiment in FIGS. 1 and 2, it is possible for further electronic components 1 to be joined to the coated surface of the cooling element 2 by a thermally conductive paste 4 (as an example of a thermal interface material), such as transistors, FETs (field effect transistors), voltage regulators, a die, a chip, a circuit board, a hybrid circuit, a printed circuit board (PCB), a lead frame, a plug, etc.

The invention is not restricted to these specific examples of electronic components 1. In principle, any electronic component 1, such as an electrical component, an electromechanical component etc. can be joined to the coated surface of the temperature-control element, here, for example, the cooling element 2, so that on the one hand the electronic component can dissipate its heat to the cooling element 2 and on the other, it is electrically insulated from the cooling element 2, thereby making it possible to prevent a short circuit with the cooling element 2.

As previously stated, it is also possible for only at least one surface region of the cooling element 2 to be coated. In other words, a partial coating, preferably a coating of functional surfaces, i.e. surface regions to which at least one electronic component 1 is connected, is carried out, in particular by means of a thermal interface material, such as a thermally conductive paste 4, as shown by way of example in the following FIG. 3.

The described method can be used on all insulating and/or thermally connected temperature-control elements 2, such as in particular cooling elements, if a component 1 is to be positioned thereon, which component is to be connected to the temperature-control element 2 both in an electrically insulated manner and thermally.

In the embodiment of the invention shown in FIGS. 1 and 2, before the electrically insulating and thermally conductive coating, for example the electro-ceramic coating 6, is applied to the surface of the component 2 to be coated, at least the surface region of the component to be coated with the electro-ceramic coating 6 can optionally also be pretreated.

In this respect, the surface region of the component 2 to be coated with the electrically insulating and thermally conductive coating, for example a ceramic coating, such as an electro-ceramic coating 6 can be pretreated, for example, by a blasting method, for example using corundum as the blasting agent. This method can remove burrs, for example, from the component surface and/or can provide or ensure a predetermined or defined surface roughness of the component 2.

In this respect, the surface region of the component 2 to be coated with the electrically insulating and thermally conductive coating, for example with the electro-ceramic coating 6 can be provided, for example, with a surface roughness within a region of R_{z}±40 μm or within a range of R_{z}=20 μm to R_{z}=60 μm, as a result of which the adhesion of the coating 6 can be additionally improved. However, the invention is not restricted to the two mentioned ranges. The surface roughness is preferably selected such that the adhesion of the electrically insulating and thermally conductive coating, for example the electro-ceramic coating 6 is improved. The invention is not restricted to this range of R_{z}=20 μm to R_{z}=60 μm. The roughness is preferably selected such that the adhesion of the electrically insulating and thermally conductive coating used in each case is improved or the adhesion of the intermediate layer is improved, if an additional intermediate layer is used as adhesive base.

Instead of corundum, it is possible to use any other material or any other combination of materials as the blasting agent for blasting a surface region of the component. Sand-blasting, shot peening, metal blasting or glass blasting etc. can be used as blasting methods. In this manner, at least the surface region of the component 2 to be coated with the electrically insulating and thermally conductive coating, for example with the electro-ceramic coating 6 can be provided with a predetermined roughness which is capable of subsequently improving the adhesion of the coating, for example the electro-ceramic coating 6.

Instead of or in addition to the pretreatment of at least the surface region of the component 2 to be coated with the electrically insulating and thermally conductive coating 6 by means of a blasting method and a blasting agent, such as corundum, it is also possible for at least one additional intermediate layer 12 to be applied to the component or to the cooling element, as shown in FIG. 2.

In this respect, the intermediate layer 12 is provided between the surface of the component or the surface of the cooling element and the subsequent electrically insulating and thermally conductive coating, for example the electro-ceramic coating 6. A material or a material combination which forms an adhesive base for the electrically insulating and thermally conductive coating, for example the electro-ceramic coating 6, is used as the material or material combination for the intermediate layer 12.

As the material for the intermediate layer 12, it is possible to use, for example, a metal or a metal alloy, such as a Ni/Al alloy or a Ni/Cr alloy, since they form an effective adhesive base. Furthermore, the intermediate layer 12 can have a layer thickness within the region of, for example, ±10 μm. The intermediate layer 12 can additionally improve the adhesion of the electrically insulating and thermally conductive coating, for example the electro-ceramic coating 6, on the component or the cooling element 2. In the embodiments according to the invention which are shown in FIGS. 1 and 2, the thickness of the electrically insulating and thermally conductive coating 6 can preferably be within a range of 15 μm to 150 μm.

However, the present invention is not restricted to the mentioned ranges for the layer thicknesses of the electrically insulating and thermally conductive coating, for example the electro-ceramic coating 6, and of the intermediate layer.

FIG. 3 is a plan view of a housing 8 of a radiator fan motor of a vehicle as an example of a temperature-control element 2, in this case a cooling element. In this respect, one part of the surface of the housing 8 is coated with an electrically insulating and thermally conductive coating, for example with an electro-ceramic coating 6, the part of the surface having a plurality of functional surfaces 9, to which one or more electronic components are subsequently connected by means of a thermal interface material, such as a thermally conductive paste. The region 10 of the surface of the housing 8 of the radiator fan motor which is not to be coated is covered or masked, for example with a plate having appropriate openings for the functional surfaces (not shown). As previously stated, an electro-ceramic 6, such as aluminium oxide, is sprayed as ceramic granules into a plasma jet. Consequently, the ceramic granules become liquefied and are deposited or applied onto the uncovered surface 11, to be coated, of the housing 8 in order to provide said surface with a ceramic coating 6.

FIG. 4 is also a plan view of a housing 8 of a radiator fan motor of a vehicle, with an electrically insulating and thermally conductive coating, for example an electro-ceramic coating 6, of, for example, only functional surfaces 9. In the embodiment shown in FIG. 4, only functional surfaces 9 to which at least one electronic component is subsequently attached, are coated with an electro-ceramic 6.

In this respect, the part of the surface of the housing 8 which does not form a functional surface is covered or masked, for example with a plate having appropriate openings for the functional surfaces (not shown), to subsequently provide only the functional surfaces 9 with a ceramic coating 6. Following the coating of the functional surfaces 9 with the electro-ceramic 6, one or more electronic components can then be connected to the functional surfaces 9, for example using a thermal interface material, for example a thermally conductive paste. In this respect, it is also possible to use as an electro-ceramic 6 aluminium oxide, for example, which is sprayed as ceramic granules into a plasma jet, the ceramic granules liquefying and being sprayed onto the uncovered functional surfaces 9, 11, to be coated, of the housing 8, in order to provide said surfaces with a ceramic coating.

In the embodiments shown in FIGS. 3 and 4, at least the surface region of the housing 8 to be provided with the electrically insulating and thermally conductive coating, for example with the electro-ceramic 6 as a ceramic coating can optionally be treated by a blasting method (for example sandblasting, shot peening, metal blasting, glass blasting etc.) and/or can be provided with at least one additional intermediate layer 12, as previously described with reference to FIG. 2.

The coating procedure of the surface 11 of the cooling element 2 and the subsequent attachment of an electronic component to the coated surface 11 affords the advantage that the thermal connection of the electronic component to the cooling element 2 can be improved and, at the same time, an electrical insulation of the electronic component from the cooling element 2 can be achieved.

A further advantage is that additional cleaning processes, such as washing or brushing the cooling element 2, for example the injection moulded housing of the radiator fan motor can be omitted. Furthermore, high scrap metal costs within production can be prevented, such costs previously being incurred as a result of short circuits between the electronic component and the cooling element 2 and entailing a considerable amount of rejected material during production.

Furthermore, it is possible to dispense with specific glass bead adhesives as the thermally conductive paste to insulate the electronics from the cooling element and instead, it is possible to use a more economical thermally conductive paste. Dispensing with glass bead adhesives also has the advantage that savings can be made during the maintenance and wear of adhesive pumps for applying the thermally conductive paste. The glass beads of the glass bead adhesive increase the wear in adhesive pumps and thus said pumps have to be maintained and replaced relatively frequently during the application of glass bead adhesives as a thermally conductive paste.

Ceramic coatings for coating the surface of the cooling element are available in different thicknesses and materials or material combinations and can thus be used worldwide for all forms of application.

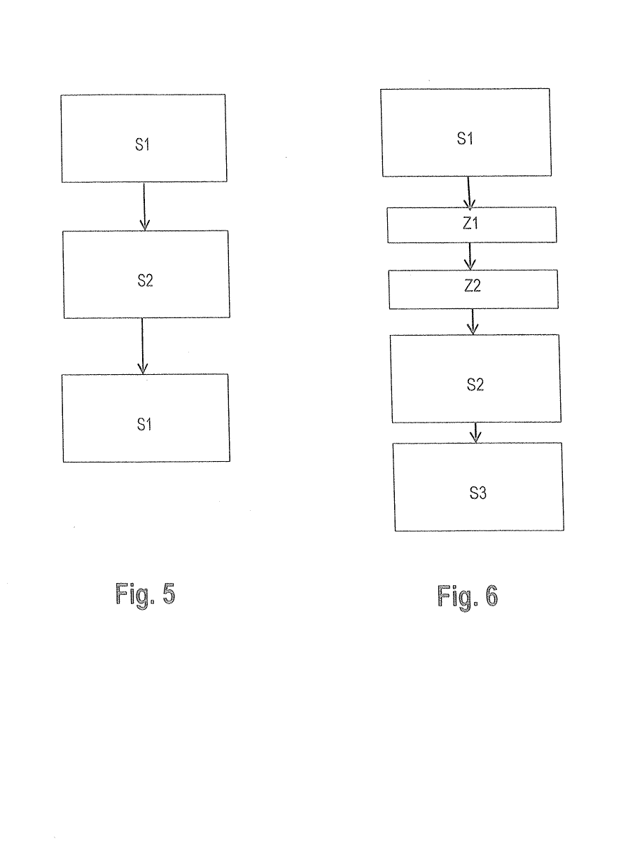

FIG. 5 is a flow chart for connecting or attaching an electronic component to a temperature-control element, here in particular a cooling element, according to the first embodiment of the invention.

In a first step S1, a temperature-control element is provided which is to be connected to at least one electronic component to control the temperature of the electronic component, in particular to cool it. In this respect, the electronic component is to be electrically arranged with respect to the temperature-control element such that it is electrically insulated from the temperature-control element.

In a second step S2, at least one surface region of the temperature-control element, for example a functional surface to which at least one electronic component is then attached, is coated with an electrically insulating and thermally conductive coating, for example a ceramic coating, such as an electro-ceramic.

The electrically insulating and thermally conductive coating is applied by a thermal spraying process. It is possible to use as the thermal spraying process, for example, flame spraying, in particular high-velocity flame spraying with a gaseous fuel, or plasma spraying, in particular atmospheric plasma spraying. In plasma spraying, the electro-ceramic or the ceramic material is sprayed under high pressure into a plasma jet for coating as ceramic granules, as a result of which, the ceramic granules become liquefied and are deposited or applied onto the surface of the temperature-control element to be coated. It is possible to use as the ceramic coating, such as an electro-ceramic coating 6, for example aluminium oxide, corundum or Al₂O₃, a mixture of, for example, 97% Al₂O₃ or corundum and 3% TiO₂ or titanium dioxide, MgAl₂O₄ or spinel, or magnesium oxide, etc. The electrically insulating and thermally conductive coating, such as the ceramic coating, for example the electro-ceramic 6, is preferably applied to the surface to be coated of the temperature-control element such that, for example, an existing surface unevenness of the temperature-control element is at least partly or completely evened out and/or a residual unevenness of the temperature-control element is coated.

In a third step S3, at least one electronic component is connected to the coated surface region of the temperature-control element, for example by a thermal interface material such as a thermally conductive paste, for example a glass bead adhesive or another suitable thermally conductive paste.

As previously stated, the temperature-control element can be a housing of a radiator fan motor of a vehicle, for example an injection moulded housing, such as an aluminium injection moulded housing. However, the invention is not restricted to a housing of a radiator fan motor of a vehicle. In principle, any temperature-control element can be used which can be thermally connected to an electronic component and also allows an electrical insulation of the electronic component.

FIG. 6 is also a flow chart for connecting or attaching an electronic component to a temperature-control element, here in particular a cooling element, according to the second embodiment of the invention.

In a first step S1, a temperature-control element is provided which is to be connected to at least one electronic component to control the temperature of the electronic component, in particular to cool it.

In a first intermediate step Z1, at least one surface region of the temperature-control element, for example a functional surface to which at least one electronic component is subsequently attached, is initially treated by a blasting method. The surface region is preferably treated by the blasting method such that the adhesion of the subsequent intermediate layer or of the electrically insulating and thermally conductive coating, for example an electro-ceramic, is improved.

In this respect, it is possible to use as the blasting method sandblasting, shot peening, metal blasting and/or glass blasting etc. to provide the surface region with, for example, a defined roughness in a range, for example, of R_{z}=20 μm to R_{z}=60 μm and/or to remove burrs and the like.

In addition or alternatively to the first intermediate step Z1, in a second intermediate step Z2, at least one intermediate layer is applied to the at least one surface region of the temperature-control element, for example a functional surface on which at least one electronic component is subsequent attached. In this respect, the at least one intermediate layer is preferably selected such that it forms an adhesive base for the electrically insulating and thermally conductive coating, for example of an electro-ceramic, which is to be subsequently applied thereto. The at least one intermediate layer can also be applied by thermal spraying onto the surface region of the temperature-control element. In this respect, it is possible to use as the thermal spraying process, for example flame spraying, in particular high-velocity flame spraying with a gaseous fuel, or plasma spraying, in particular atmospheric plasma spraying.

The at least one intermediate layer can be a metal alloy, for example of chromium, nickel, copper and/or aluminium, in particular a nickel-chromium alloy and/or a nickel-aluminium alloy. Furthermore, the intermediate layer can have a thickness of, for example, 10 μm, although the invention is not restricted to this thickness value.

In a second subsequent step S2, the at least one surface region of the temperature-control element which has been previously treated by a blasting method in intermediate step Z1 and/or has been provided with at least one intermediate layer in intermediate step Z2 is coated with an electrically insulating and thermally conductive coating, for example with an electro-ceramic.

The electrically insulating and thermally conductive coating is applied by a thermal spraying process. In this respect, it is possible to use as the thermal spraying process for example flame spraying, in particular high-velocity flame spraying with a gaseous fuel, or plasma spraying, in particular atmospheric plasma spraying. In plasma spraying, the electro-ceramic or the ceramic material is sprayed under high pressure into a plasma jet for coating as ceramic granules, consequently the granules or ceramic granules become liquefied and are deposited or applied onto the surface of the temperature-control element to be coated. As stated previously, it is possible to use as the ceramic coating, for example an electro-ceramic coating 6, for example aluminium oxide, corundum or Al₂O₃, a mixture of, for example, 97% Al₂O₃ or corundum and 3% TiO₂ or titanium dioxide, MgAl₂O₄ or spinel, and/or magnesium oxide, etc. The electrically insulating and thermally conductive coating, for example the electro-ceramic 6, is preferably applied to the surface to be coated of the temperature-control element such that, for example, an existing surface unevenness of the temperature-control element is at least partly or completely evened out and/or a residual unevenness of the temperature-control element is coated.

In a third step S3, at least one electronic component is connected to the coated surface region of the temperature-control element, for example by means of a thermal interface material such as a thermally conductive paste, for example a glass bead adhesive or another suitable thermally conductive paste.

As previously stated, the temperature-control element can be a housing of a radiator fan motor of a vehicle, for example an injection moulded housing, such as an aluminium injection moulded housing. However, the invention is not restricted to a housing of a radiator fan motor of a vehicle. In principle, any temperature-control element can be used which can be thermally connected to an electronic component and also allows an electrical insulation of the electronic component.

To provide a surface of the component or of the cooling element with a defined roughness and/or to remove burrs etc, apart from the mentioned blasting method, it is also possible to use any other suitable method or any other suitable combination of methods. Thus, for example, etching, polishing etc, can be used as further methods, to name but two of a large number of examples.

Although the present invention has been described above in full with reference to preferred embodiments, it is not restricted thereto, but can be modified in many different ways.

### List of Reference Numerals

1 electronic component
2 temperature-control element/cooling element
3 circuit board
4 thermal interface material or thermal connecting or joining material (for example thermally conductive paste)
5 unevenness
6 electrically insulating and thermally conductive coating, in particular ceramic coating (for example the electro-ceramic coating)
7 residual unevenness
8 housing
9 functional surface
10 uncoated surface
11 coated surface
12 intermediate layer

1. Temperature-control element, having at least one surface region with an electrically insulating and thermally conductive coating, in particular a ceramic coating, provided on said surface region, wherein attached to the coating is at least one electronic component which is thermally connected to the temperature-control element and is configured to be electrically insulating with respect to the temperature-control element.

2. Temperature-control element according to claim 1, wherein the at least one surface region is surface-treated, in particular by a blasting method, by etching and/or polishing.

3. Temperature-control element according to claim 2, wherein the at least one surface region has a defined surface roughness, preferably a surface roughness within a range of R_{z}=20 μm to R_{z}=60 μm, as a result of the surface treatment.

4. Temperature-control element according to claim 1, wherein the at least one surface region is provided with at least one intermediate layer, said intermediate layer being configured in particular as an adhesive base for the coating.

5. Temperature-control element according to claim 4, wherein the intermediate layer is a metal alloy and is in particular a nickel, chromium, copper and/or aluminium alloy.

6. Temperature-control element according to claim 4, wherein the intermediate layer is applied to the at least one surface region by thermal spraying.

7. Temperature-control element according to claim 1, wherein the coating is formed on the surface region in order to at least partly or completely even out unevennesses and/or impurities of the surface region.

8. Temperature-control element according to claim 1, wherein the electronic component is connected to the coating on the surface region or on the at least one intermediate layer by a thermal interface material, in particular by a thermally conductive paste.

9. Temperature-control element according to claim 1, wherein the coating at least partly or completely consists of aluminium oxide, Al₂O₃, a mixture of 97% Al₂O₃, and 3% TiO₂, MgAl₂O₄ and/or magnesium oxide and in particular has a thickness ranging between 15 μm and 150 μm.

10. Temperature-control element according to claim 1, wherein the coating can be applied to the surface region of the temperature-control element by thermal spraying and preferably by high-velocity flame spraying or plasma spraying, for coating the surface region.

11. Temperature-control element according to claim 1, wherein the temperature-control element is configured as a cooling element, in particular as a housing of a radiator fan motor of a vehicle.

12. Temperature-control element according to claim 1, wherein the electronic component is configured as an electrical, electronic or electromechanical component, in particular as a transistor, a hybrid circuit, a printed circuit board, a chip, a plug, a stator circuit, a die, a lead frame, a circuit board, a field effect transistor or a voltage regulator.

13. Method for attaching at least one electronic component to a temperature-control element, comprising the steps:
providing a temperature-control element;
applying an electrically insulating and thermally conductive coating, in particular a ceramic coating, to at least one surface region of the temperature-control element;
attaching at least one electronic component to the coating of the temperature-control element, the electronic component being thermally connected to the temperature-control element and being electrically insulated from the temperature-control element.

14. Method according to claim 13, wherein the step of applying an electrically insulating and thermally conductive coating comprises the step of blasting the at least one surface region of the temperature-control element and/or coating the at least one surface region with at least one intermediate layer, and subsequently applying the electrically insulating and thermally conductive coating.

15. Method according to claim 13, wherein the coating and/or the intermediate layer is applied by thermal spraying and in particular by high-velocity flame spraying or plasma spraying.

16. Method according to claim 13, wherein for applying the coating, a surface region, which is not to be coated, of the temperature-control element is covered or masked before said coating is applied.
